(19) United States
(12) Patent Application Publication
(10) Pub. No.: US 2021/0193701 A1
(43) Pub. Date: Jun. 24, 2021

(54) IMAGING SYSTEMS AND METHODS FOR GENERATING IMAGE DATA IN AMBIENT LIGHT CONDITIONS

(71) Applicant: SEMICONDUCTOR COMPONENTS INDUSTRIES, LLC, Phoenix, AZ (US)

(72) Inventor: Yoshihito HIGASHITSUTSUMI, Kashiwa-cho (JP)

(73) Assignee: SEMICONDUCTOR COMPONENTS INDUSTRIES, LLC, Phoenix, AZ (US)

(21) Appl. No.: 16/722,843

(22) Filed: Dec. 20, 2019

(51) Int. Cl. H01L 27/146; G01S 17/894; G01S 7/4863; H04N 5/3745; H04N 5/378

(52) U.S. Cl. CPC H01L 27/1461; H01L 27/14647; H01L 27/14603; H04N 5/378; G01S 17/894; G01S 7/4863; H04N 5/37452; H01L 27/14614

(57) ABSTRACT

An imaging system may include a light source for generating pulses of light and an image sensor for collecting reflected light from the generated pulses of light. The image sensor may include an array of pixels, each having a photosensitive element, a floating diffusion region, and two charge storage structures interposed between the photosensitive element and the floating diffusion region. A potential barrier structure may be interposed between the photosensitive element and the two charge storage structures. The photosensitive element may generate charge in response to ambient light and may set the potential barrier level of the potential barrier structure using the generated charge. The imaging system may perform time-of flight information generation using the potential barrier structures in each of the pixels.

### BACKGROUND

This relates generally to imaging devices, and more particularly, to imaging devices for generating image data (e.g., time-of-flight (TOF) information) in ambient light conditions.

Image sensors are commonly used in electronic devices such as cellular telephones, cameras, and computers to capture images. In a typical arrangement, an image sensor includes an array of image pixels arranged in pixel rows and pixel columns. Circuitry may be coupled to each pixel column for reading out image signals from the image pixels.

A typical image pixel contains a photodiode for generating charge in response to incident light. The image pixel may also include a charge storage region for storing charge that is generated in the photodiode. In general, the image sensor can be used to generate a color image. However, some applications require capturing other image information (e.g., TOF information). Difficulties can arise when capturing the image information in certain ambient light conditions such as under sunlight because of saturation issues and when attempting to reduce noise.

It would therefore be desirable to be able to provide imaging systems with improved image data generating capabilities.

### BRIEF DESCRIPTION OF THE DRAWINGS

FIG. 1 is a diagram of an illustrative electronic device having an image sensor and processing circuitry for capturing images in accordance with some embodiments.

FIG. 2 is a diagram of an illustrative pixel array and associated readout circuitry for reading out image signals from the pixel array in accordance with some embodiments.

FIG. 3 is a circuit diagram of an illustrative image pixel having an adjustable potential barrier structure coupled to a photosensitive element in accordance with some embodiments.

FIG. 4 is a block diagram of an illustrative imaging system configured to generate time-of-flight information in accordance with some embodiments.

FIG. 5 is an illustrative flowchart for operating an imaging system based on a potential barrier structure adjustable using ambient light information in accordance with some embodiments.

FIG. 6 is an illustrative flowchart for operating an imaging system in a time-of-flight mode of operation in accordance with some embodiments.

FIG. 7 is an illustrative timing diagram for operating an imaging system in a time-of-flight mode of operation based on ambient light information in accordance with some embodiments.

### DETAILED DESCRIPTION

Electronic devices such as digital cameras, computers, cellular telephones, and other electronic devices may include image sensors that gather incoming light to capture an image. The image sensors may include arrays of image pixels. The pixels in the image sensors may include photosensitive elements such as photodiodes that convert the incoming light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the image pixels and readout circuitry for reading out image signals corresponding to the electric charge generated by the photosensitive elements.

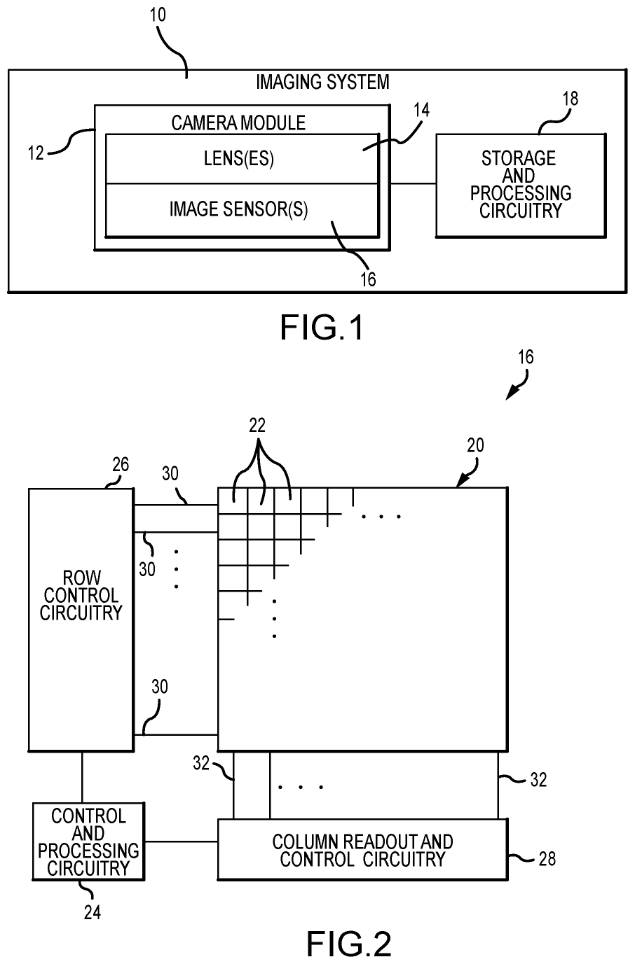

FIG. 1 is a diagram of an illustrative imaging system such as an electronic device that uses an image sensor to capture images. Electronic device 10 of FIG. 1 may be a portable electronic device such as a camera, a cellular telephone, a tablet computer, a webcam, a video camera, a video surveillance system, an automotive imaging system, a video gaming system with imaging capabilities, or any other desired imaging system or device that captures digital image data. Camera module 12 (sometimes referred to as an imaging module) may be used to convert incoming light into digital image data. Camera module 12 may include one or more lenses 14 and one or more corresponding image sensors 16. Lenses 14 may include fixed and/or adjustable lenses and may include microlenses formed on an imaging surface of image sensor 16 and other macro lenses. During image capture operations, light from a scene may be focused onto image sensor 16 by lenses 14. Image sensor 16 may include circuitry for converting analog pixel image signals into corresponding digital image data to be provided to storage and processing circuitry 18. If desired, camera module 12 may be provided with an array of lenses 14 and an array of corresponding image sensors 16.

Storage and processing circuitry 18 may include one or more integrated circuits (e.g., image processing circuits, microprocessors, storage devices such as random-access memory and non-volatile memory, etc.) and may be implemented using components that are separate from the camera module and/or that form part of the camera module (e.g., circuits that form part of an integrated circuit that includes image sensors 16 or an integrated circuit within the module that is associated with image sensors 16). When storage and processing circuitry 18 is included on different integrated circuits (e.g., chips) than those of image sensors 16, the integrated circuits with circuitry 18 may be vertically stacked or packaged with respect to the integrated circuits with image sensors 16. Image data that has been captured by the camera module may be processed and stored using processing circuitry 18 (e.g., using an image processing engine on processing circuitry 18, using an imaging mode selection engine on processing circuitry 18, etc.). Processed image data may, if desired, be provided to external equipment (e.g., a computer, external display, or other device) using wired and/or wireless communications paths coupled to processing circuitry 18.

As shown in FIG. 2, image sensor 16 may include a pixel array 20 containing image sensor pixels 22 arranged in rows and columns (sometimes referred to herein as image pixels or pixels) and control and processing circuitry 24. Array 20 may contain, for example, hundreds or thousands of rows and columns of image sensor pixels 22. Control circuitry 24 may be coupled to row control circuitry 26 and image readout circuitry 28 (sometimes referred to as column control circuitry, readout circuitry, processing circuitry, or column readout circuitry). Row control circuitry 26 may receive row addresses from control circuitry 24 and supply corresponding row control signals such as reset, row-select, charge transfer, dual conversion gain, and readout control signals to pixels 22 over row control paths 30. One or more conductive lines such as column lines 32 may be coupled to each column of pixels 22 in array 20. Column lines 32 may be used for reading out image signals from pixels 22 and for supplying bias signals (e.g., bias currents or bias voltages) to pixels 22. If desired, during pixel readout operations, a pixel row in array 20 may be selected using row control circuitry 26 and image signals generated by image pixels 22 in that pixel row can be read out along column lines 32.

Image readout circuitry 28 may receive image signals (e.g., analog pixel values generated by pixels 22) over column lines 32. Image readout circuitry 28 may include sample-and-hold circuitry for sampling and temporarily storing image signals read out from array 20, amplifier circuitry or a multiplier circuit, analog to digital conversion (ADC) circuitry, bias circuitry, column memory, latch circuitry for selectively enabling or disabling the column circuitry, or other circuitry that is coupled to one or more columns of pixels in array 20 for operating pixels 22 and for reading out image signals from pixels 22. ADC circuitry in readout circuitry 28 may convert analog pixel values received from array 20 into corresponding digital pixel values (sometimes referred to as digital image data or digital pixel data). Image readout circuitry 28 may supply digital pixel data to control and processing circuitry 24 and/or processor 18 (FIG. 1) for pixels in one or more pixel columns.

Pixel array 20 may be provided with a filter array having multiple (color) filter elements (each corresponding to a respective pixel) which allows a single image sensor to sample light of different colors or sets of wavelengths. As an example, image sensor pixels such as the image pixels in array 20 may be provided with a color filter array having red, green, and blue filter elements, which allows a single image sensor to sample red, green, and blue (RGB) light using corresponding red, green, and blue image sensor pixels arranged in a Bayer mosaic pattern.

The Bayer mosaic pattern consists of a repeating unit cell of two-by-two image pixels, with two green image pixels (under filter elements that pass green light) diagonally opposite one another and adjacent to a red image pixel (under a filter element that passes red light) diagonally opposite to a blue image pixel (under a filter element that passes blue light). In another suitable example, the green pixels in a Bayer pattern may be replaced by broadband image pixels having broadband color filter elements (e.g., clear color filter elements, yellow color filter elements, etc.). In yet another example, one of the green pixels in a Bayer pattern may be replaced by infrared (IR) image pixels formed under IR color filter elements and/or the remaining red, green, and blue image pixels may also be sensitive to IR light (e.g., may be formed under filter elements that pass IR light in addition to light of their respective colors). These examples are merely illustrative and, in general, filter elements of any desired color and/or wavelength and in any desired pattern may be formed over any desired number of image pixels 22.

Additionally, separate microlenses may be formed over each image pixel 22 (e.g., with light or color filter elements interposed between the microlenses and image pixels 22). The microlenses may form an array of microlenses that overlap the array of light filter elements and the array of image sensor pixels 22. Each microlens may focus light from an imaging system lens onto a corresponding image pixel 22, or multiple image pixels 22, if desired.

If desired, image sensor 16 may include an integrated circuit package or other structure in which multiple integrated circuit substrate layers or chips are vertically stacked with respect to each other. In this scenario, one or more of circuitry 24, 26, and 28 may be vertically stacked above or below array 20 within image sensor 16. If desired, lines 32 and 30 may be formed from vertical conductive via structures (e.g., through-silicon vias or TSVs) and/or horizontal interconnect lines in this scenario.

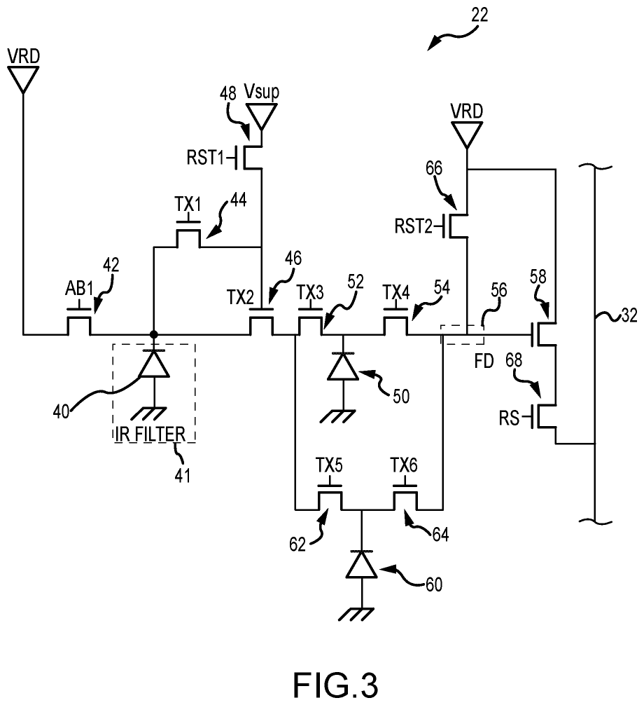

FIG. 3 is a circuit diagram of an illustrative image pixel 22. As shown in FIG. 3, pixel 22 may include a photosensitive element such as photodiode 40. A light filter structure such as IR filter 41 and/or other color filters may be included, and incoming light may pass through the light filter structure before being collected in photodiode 40. In such a way, photodiode 40 may be sensitive to only light that passes the light filter structure. Photodiode 40 may generate charge (e.g., electrons) in response to receiving impinging photons. The amount of charge that is collected by photodiode 40 depends on the intensity of the impinging light and the exposure duration (or integration time).

Pixel 22 may include transistor 42 that couples photodiode 40 to a voltage source supplying voltage VRD. In particular, transistor 42 may reset photodiode 40 to voltage VRD and may be deactivated when photodiode 40 accumulates charge. Photodiode 40 may be electrically connected to floating diffusion region 56 through transistor 46 (e.g., transistor 46 may have a first source-drain terminal coupled to photodiode 40 and may have a second source-drain terminal coupled to floating diffusion region 56). Transistor 46 may have a gate terminal (sometimes referred to herein as a control terminal) coupled to transistor 44.

Transistor 44 may electrically connect photodiode 40 to the gate terminal of transistor 46. In particular, transistor 46 may be configured (by receiving different voltages at its gate terminal) to provide a potential barrier (sometimes referred to herein as a voltage barrier) between photodiode 40 and floating diffusion region 56 (and/or between photodiode 40 and other charge storage structures). By connecting photodiode 40 to the gate terminal of transistor 46, charge generated by photodiode 40 may be used to control the potential barrier level. As an example, photodiode 40 may be configured to generate charge in response to one or more ambient light source(s). The generated charge based on the ambient light source may determine the magnitude of the potential barrier or the potential barrier level. Additionally, transistor 48 may be coupled to the gate terminal of transistor 46 and may provide a voltage source supplying voltage Vsup. Voltage Vsup may be a reset voltage for transistor 46 and may be used to reset a gate voltage supplied from transistor 44 to transistor 46.

As an example, in one mode of operation for pixel 22, transistor 44 may always be deactivated, and pixel 22 may operate without transistor 46 providing the potential barrier. In this case, if photodiode 40 is configured to receive color light (e.g., RGB light), pixel 22 may be used as if transistor 44 were omitted. If desired, in another mode of operation for pixel 22, transistor 44 may at least sometimes be activated during operation, and pixel 22 may operate with transistor 46 providing the potential barrier.

Transistor 46 may be coupled to floating diffusion region 56 via two parallel paths. The first parallel path may include a charge storage structure such as storage diode 50, transistor 52 interposed between transistor 46 and storage diode 50, and transistor 54 interposed between storage diode 50 and floating diffusion region 56. The second parallel path may include a charge storage structure such as storage diode 60, transistor 62 interposed between transistor 46 and storage diode 60, and transistor 64 interposed between storage diode 60 and floating diffusion region 56. Respective charges may be stored and/or integrated at storage diodes 50 and 60 and subsequently transferred to floating diffusion region 56 for readout. The use of storage diodes is merely illustrative. If desired, any other types of suitable charge storage structures may be used.

Floating diffusion region 56 (sometimes referred to herein as a charge storage structure) may be a doped semiconductor region (e.g., a region in a silicon substrate that is doped by ion implantation, impurity diffusion, or other doping process). Floating diffusion region 56 may have an associated charge storage capacity. Transistor 66 may couple floating diffusion region 56 to a voltage source supplying voltage VRD. When transistor 66 is activated, floating diffusion region 56 may be reset to voltage VRD.

Floating diffusion region 56 may be coupled to readout transistors 58 and 68. In particular, the charge stored at floating diffusion region 56 may be read out using row select transistor 58. The charges stored at floating diffusion region 56 may include charge associated with a reset level signal, charge associated with an image level signal, or other types of charge. Row select transistor 68 may have a gate terminal that is controlled by a row select signal (i.e., signal RS). When the row select signal is asserted, transistor 68 is turned on and a corresponding pixel output signal (e.g. an output signal having a magnitude that is proportional to the amount of charge at floating diffusion region 56), is passed onto a pixel output path and column line 32.

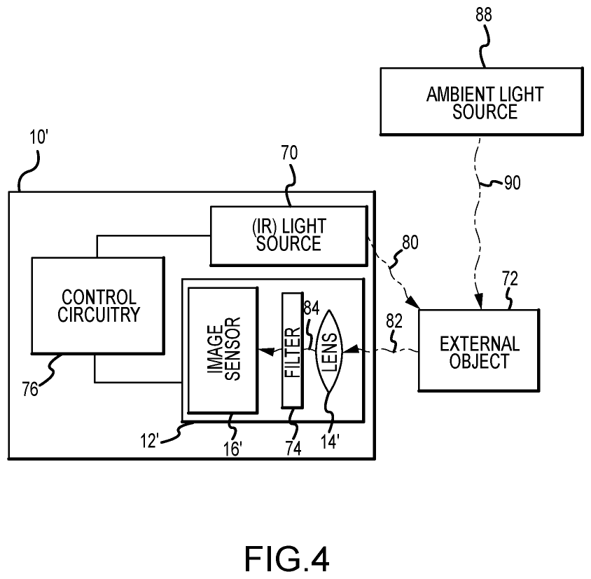

By using pixels such as pixel 22 shown in FIG. 3, an imaging system may be configured to efficiently generate TOF information (sometimes referred to as pulsed light information) in a first mode of operation as well as color light information in a second mode operation. FIG. 4 shows an illustrative imaging system (e.g., imaging system 10′) that may use pixels 22 in FIG. 3. If desired, imaging system 10′ may be implemented in a similar manner as imaging system 10 in FIG. 1 (e.g., may have similar components and interconnections as described in connection with imaging system 10 in FIG. 1).

As shown in FIG. 4, imaging system 10′ may include light source 70. Light source 70 may be an infrared (IR) light source that generates IR light (e.g., pulses of IR light) and may irradiate portions of an environment using the IR light. As an example, light source 70 may shine IR light on external object 72 (as indicated by light 80). External object 72 may be a person, a sign, an electronic device, or any other object in the environment of imaging system 10′. Object 72 may be configured to reflect some amount of light from light source 70. Light source 70 may be a light-emitting diode or any other light-emitting device operable to generate pulsed light of a wavelength or a band of wavelengths (e.g., wavelengths associated with IR light). If desired, light source 70 may generate no colored light (e.g., do not generate RGB or color light, or visible light to the human eye) or may generate light outside of the visible spectrum.

If desired, light source 70 may generate coded light (e.g., patterned light), which is used to generate a reflected coded light image for object 72, which can be decoded to determine depth information (e.g., distance of object from imaging system 10′ and/or depth of object). More specifically, coded light may refer to a light pattern that can be projected onto a 3-D object to generate a corresponding 2-D image based on the reflected pattern from the projection. The distortion in the 2-D representation of the reflected pattern may provide depth data for the 3-D object. If desired, the coded light generated from light source 70 may be pulsed to reduce power or may be time-coded light.

The light reflected from the external object may be collected by camera module 12′. In particular, reflected light 82 may pass through an imaging system lens such as lens 14′. Lens 14′ may direct reflected light 82 through filter 74 (sometimes referred to herein as a filter structure or filter layer) to image sensor 16′ (e.g., light 84). Filter 74 may be a visible light cut filter that passes IR light or may be a multi-band filter that passes some visible light (e.g., RGB light) and IR light. In other words, filter 74 may be configured to pass through any reflected IR light (as well as any desirable color light).

If desired, image sensor 16′ may be a monochrome image sensor that collects RGB light and IR light (e.g., filter 74 may be an RGBIR filter), and light source 70 may be a light source that generates light for viewing purposes of a user (e.g., light that illuminates an object viewed by the user).

Image sensor 16′ may generate image signals based on pulsed light information from the light reflected off of external object 72. The pulsed light information may refer to any information gather based on the irradiation of light source 70 (e.g., based on ray 80, reflected ray 82, and/or directed light 84). As examples, the pulsed light information may convey information about external object 72, identify external object 72, or otherwise convey information about an operational environment of imaging system 10′. However, external object 72 may also be illuminated by an ambient light source (e.g., the Sun) generating ambient light 90. The illumination by the ambient light source may undesirably affect reflected light 84 gathered by image sensor 16′. As an example, ambient light 90 may cause large amounts of light to be reflected from object 72 and collected by image sensor 16′, thereby leading to oversaturation issues.

To mitigate these issues, image sensor 16′ may use pixels 22 of the type shown in FIG. 3. In particular, pixels 22 in image sensor 16′ may be configured to capture the ambient light and to use the captured ambient light to account for any ambient light during normal operation of image sensor operation (e.g., pulse light or TOF information generation operations). As an example, transistor 46 in pixel 22 (FIG. 3) may be configured to set a potential barrier associated with the ambient light such that only charge above the potential barrier (e.g., above the ambient light voltage level) is transferred to a charge storage structure and used by the image sensor.

Control circuitry 76 may be coupled to camera module 12′ and light source 70. If desired, control circuitry 76 may be implemented as a portion of control circuitry 24, control circuitry 26, or control circuitry 28 in FIG. 2, may be implemented as a portion of processing circuitry 18 in FIG. 1, may be implemented as separate circuitry from these circuitries, or may be implemented as any combination of circuitries. Control circuitry 76 may provide and receive control signals, clocking or timing signals, data signals, or any other types of signals to and from light source 70 and/or camera module 12′ to efficiently generate pulsed light and pulsed light information based on the pulsed light.

As an example, control circuitry 76 may include a timing generator. In particular, the timing generator generate signals to deactivate light source 70 when image sensor 16′ collects ambient light information and/or during non-TOF modes of operation. The timing generator may also generate signals to activate light source 70 when image sensor 16′ is configured by the ambient light information (e.g., has pixels configured with the appropriate potential barriers) and is performing pulsed light or TOF information generation operation. As another example, control circuitry 76 may include processing circuitry such as a depth processor. The depth processor may receive TOF information from image sensor 16′ and may process the TOF information to generate depth information for external object 72 and/or the environment or scene.

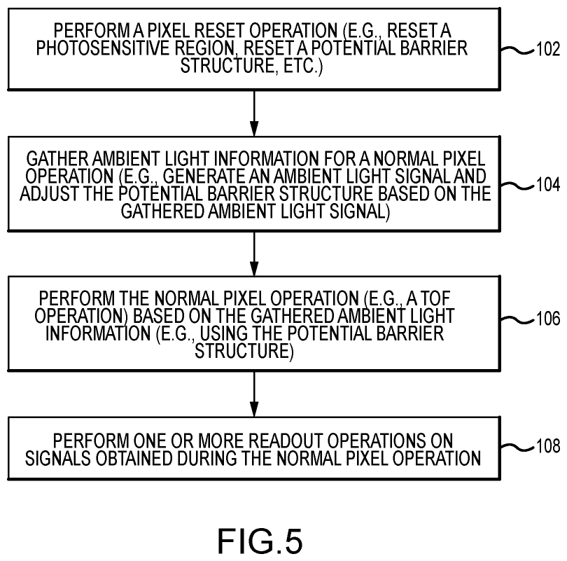

FIG. 5 is an illustrative flowchart for operating an image pixel or an imaging system containing the image pixel in the presence of ambient light. As an example, the flowchart of FIG. 5 may be described in connection with a pixel such as pixel 22 in FIG. 3 and may be described in connection with imaging system 10′ in FIG. 4. This is merely illustrative, and the flowchart of FIG. 5 may describe the operation of any other suitable pixel or imaging system.

At step 102, control circuitry in an imaging system (e.g., control circuitry 24 and/or control circuitry 26 in FIG. 2, control circuitry 76 in FIG. 4, etc.) may perform a pixel reset operation on one or more pixels in the imaging system (e.g., pixel 22 in FIG. 3). In particular, the control circuitry may use one or more control signals (e.g., control signals AB1, RST1, RST2, TX4, and TX6, in FIG. 3) to reset a photosensitive element (e.g., photodiode 40 in FIG. 3) to a reference voltage and to reset a potential barrier in a potential barrier structure (e.g., transistor 46 in FIG. 3) to a reference potential barrier level. If desired, during the same time period, the control circuitry may perform any other suitable reset operations.

At step 104, the control circuitry may control the pixel to gather ambient light information for pixel operation. In particular, the control circuitry may control the photosensitive element to begin generating and storing charge in response to incident (ambient) light. In other words, the photodiode may generate an ambient light signal. The control circuitry may use one or more control signals (e.g., may assert control signal TX1 in FIG. 3) to adjust the potential barrier structure based on the generated ambient light signal. More specifically, the control signal may electrically connect photodiode to the control terminal of the potential barrier structure (e.g., gate terminal of the potential barrier transistor) to set the potential barrier level using the charge generated at the photodiode and associated with the ambient light.

At step 106, the control circuitry may control the pixel to perform a normal pixel operation such as a TOF information generation operation based on (e.g., using) the potential barrier structure having a potential barrier level set by the charge associated with ambient light generated in step 104 or the voltage associated with the ambient light charge generated in step 104. In particular, during the normal pixel operation, the photodiode in the pixel may generate one or more sets of charge. The one or more generated sets of charge may pass through the potential barrier structure before being stored and/or integrated at one or more charge storage structures. The potential barrier structure may pass only a portion of each charge in excess of an ambient light portion. In other words, the potential barrier may effectively remove an ambient light portion of each charge (using the potential barrier) and pass only the excess portion of each charge for storage at the charge storage structures. The ambient light portion of each charge may be temporarily held at the photodiode before being removed by a photodiode reset operation.

In other words, the potential barrier structure may effectively perform an ambient light subtraction operation on each set of charge generated by the photodiode during normal pixel operation. By performing the ambient light subtract operation, the multiple sets of charge may be integrated at the charge storage structures to improve signal-to-noise ratio (SNR) and reduce oversaturation of the charge storage structures.

At step 108, the control circuitry may control the pixel to perform one or more readout operations on the signals obtained during the normal pixel operation. In particular, the control circuitry may use control signals to readout charge stored at the charge storage structures (e.g., storage diodes 50 and 60 in FIG. 3) through the floating diffusion region (e.g., floating diffusion region 56 in FIG. 3) and using the readout transistors (e.g., transistors 58 and 68 in FIG. 3).

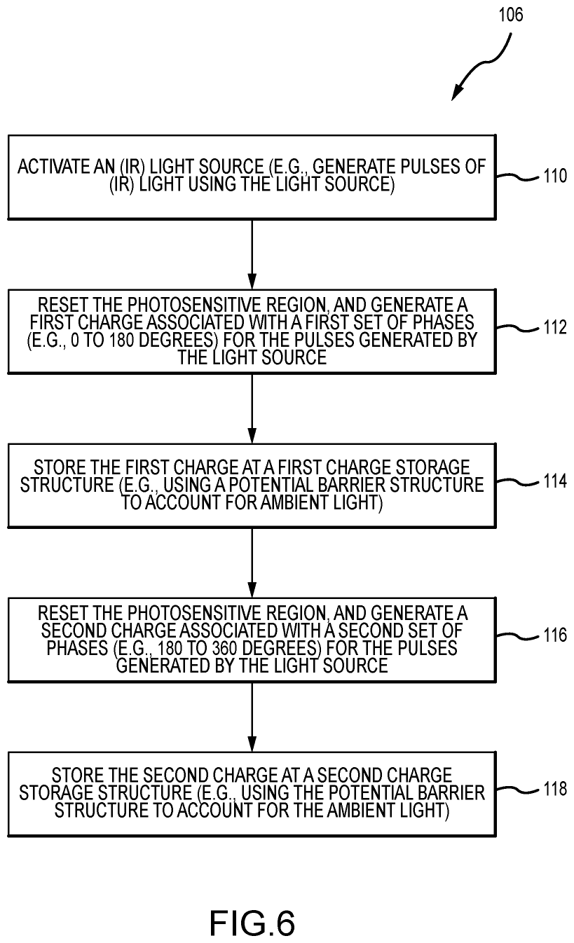

FIG. 6 is an illustrative flowchart for operating an image pixel or an imaging system containing the image pixel in a time-of-flight mode of operation. As an example, the flowchart of FIG. 6 may be described in connection with a pixel such as pixel 22 in FIG. 3, may be described in connection with imaging system 10′ in FIG. 4, and may be described in connection with step 106 in FIG. 5 (e.g., step 106 in FIG. 5 may include steps 110-118 in FIG. 6). This is merely illustrative, and the flowchart of FIG. 6 may describe the operation of any other suitable pixel or imaging system, or in combination with any other suitable steps.

At step 110, the control circuitry (e.g., using a timing controller in control circuitry 76 in FIG. 4) may use one or more control signals to activate a light source (e.g., light source 70 in FIG. 4). The activated light source may generate pulses of (IR) light that irradiates an environment, scene, or object (e.g., object 72 in FIG. 4) to perform a TOF operation. The light source may remain activated until the end of the TOF operation (e.g., until after step 118, until after multiple sets of steps 110-118 have been performed, etc.).

At step 112, the control circuitry may use one or more control signals to reset the photosensitive element (e.g., photodiode 40 in FIG. 3), and to generate a first charge associated with a first set of phases of a pulse in the pulsing light source. As an example, the first set of phases may be phases between 0 degrees and 180 degrees. This is merely illustrative. If desired, any other sets of phases may be used.

At step 114, the control circuitry may use one or more control signals to store the first charge at a first charge storage structure (e.g., storage diode 50 in FIG. 3). In particular, the first charge may pass through the potential barrier set by an ambient light voltage at the potential barrier structure (e.g., transistor 46 in FIG. 3) before being stored at the first charge storage structure. This may remove an ambient light portion of the first charge and store only the portion of the first charge in excess of the ambient light portion in the first charge storage structure.

At step 116, the control circuitry may use one or more control signals to reset the photosensitive element and to generate a second charge associated with a second set of phases of the pulse in the pulsing light source. As an example, the second set of phases may be phases between 180 degrees and 360 degrees. This is merely illustrative. If desired, any other sets of phases may be used. As an example, sets of phases beginning at 90 degrees and 270 degrees may be used.

At step 118, the control circuitry may use one or more control signals to store the second charge at a second charge storage structure (e.g., storage diode 60 in FIG. 3). In particular, the second charge may also pass through the potential barrier set by an ambient light voltage at the potential barrier structure before being stored at the second charge storage structure. This may remove an ambient light portion of the second charge and store only the portion of the second charge in excess of the ambient light portion in the second charge storage structure.

Steps 112-118 may be repeated for each pulse of light generated by the activated light source. The set of charges associated with the first set of phases for the light pulses may all separately be generated at the photodiode while repeating step 112. The set of charges associated with the first set of phases for the light pulses may all be integrated at the first charge storage structure while repeating step 114. The set of charges associated with the second set of phases for the light pulses may all separately be generated at the photodiode while repeating step 116. The set of charges associated with the second set of phases for the light pulses may all be integrated at the second charge storage structure while repeating step 118. The two integrated charges stored respective at the first and second charge storage structures may be read out during step 108 in FIG. 5 (as an example).

By separately gathering charge for the two sets of phases, the imaging system may be configured generate (TOF) information for two opposite phases for each light pulse at the same time (e.g., in an interleaved manner, during the same frame, etc.). The use of two separate sets of phases is merely illustrative. If desired, an imaging system may separate each pulse into more than two sets of phases for separate storage at corresponding charge storage structures. As an example, two frames may be used to gather TOF information for four different sets of phases or two adjacent pixels may be used to gather TOF information for four different sets of phases during a single frame. If desired, an imaging system may not separate each pulse at all and may use pixels with only a single storage diode or may combine signals from multiple storage diodes, as examples.

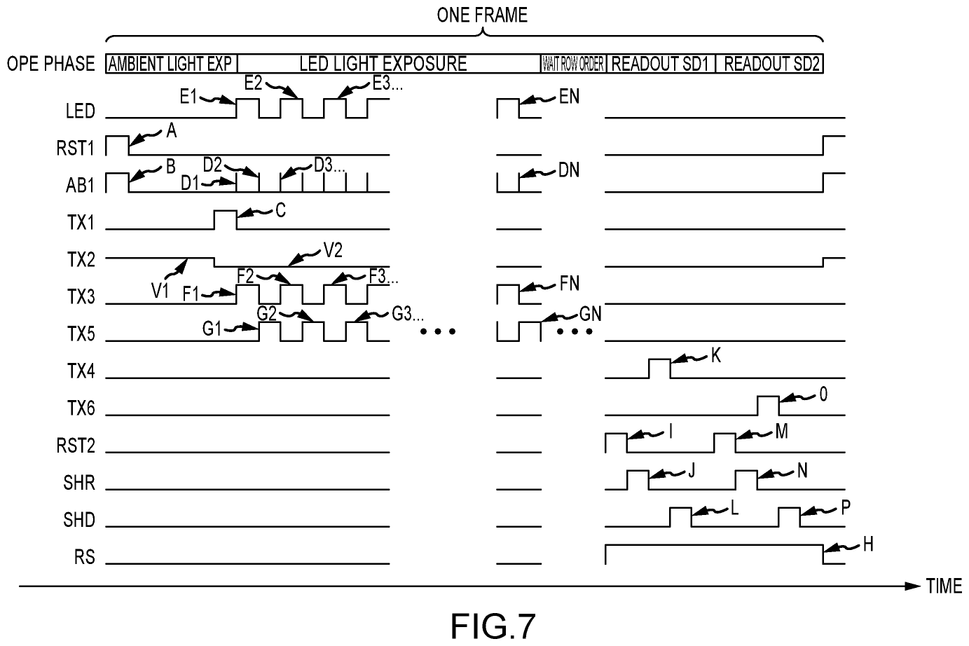

FIG. 7 is an illustrative timing diagram for operating an imaging system having ambient light subtraction capabilities such as imaging system 10′ in FIG. 4 that includes pixels 22 in FIG. 3. As shown in FIG. 7, one image frame time period may include an ambient light exposure time period, a light source (LED) exposure time period, a row order waiting time period, a first readout time period, and a second readout time period.

During the ambient light exposure time period, control circuitry such as control circuitry 76 in FIG. 4 may assert control signal RST1 (e.g., assertion A) to activate transistor 48 in FIG. 3, thereby resetting the gate terminal voltage of transistor 46 to voltage Vsup. The control circuitry may also assert control signal AB1 (e.g., assertion B) to activate transistor 42 in FIG. 3, thereby resetting photodiode 40 to voltage VRD. During the ambient light exposure time period, light source 70 in FIG. 4 may be deactivated, and photodiode 40 may generate charge corresponding to ambient light.

After a suitable time period (e.g., at the end of the ambient light exposure time period), the control circuitry may assert control signal TX1 (e.g., assertion C) to activate transistor 44. By activating transistor 44, the generated charge corresponding to the ambient light may set the voltage barrier level of transistor 46 (e.g., by providing a gate voltage different than a reference voltage such as voltage Vsup previously supplied to the gate terminal of transistor 46). As shown in FIG. 7, the gate terminal voltage of transistor 46 (indicated by signal TX2) may be at a first voltage level V1 (e.g., voltage Vsup) after assertion A. After assertion C, the gate terminal voltage of transistor 46 (indicated by signal TX2) may shift to a second voltage level V2. Voltage level V2 may be associated with the voltage of the generated ambient light charge.

After signal TX2 has shifted to voltage level V2, the light source exposure time period may begin. During the light source exposure time period, signal LED which controls light source 70 may be periodically asserted (e.g., assertions E1, E2, E3, . . . , EN) to periodically activate or pulse light source 70. Each pulse time period may be separated into two sets of phases (e.g., 0 degrees to 180 degrees and 180 degrees to 360 degrees). Photodiode 40 may be configured to separately generate charge associated with each of the two sets of phases for each pulse time period.

As an example, the first set of phases corresponding to 0 degrees to 180 degrees may be when the signal LED is asserted, and the second set of phases corresponding to 180 degrees to 360 degrees may be when the signal LED is deasserted. This is merely illustrative. If desired, the assertion and deassertion time periods during each pulse may be different (e.g., light source pulse duty may be different than 50%).

The control circuitry may assert control signal AB1 (e.g., assertions D1, D2, D3, . . . , DN) to activate transistor 42 and reset photodiode 40. Photodiode 40 may generate charge between pairs of consecutive assertions D. As an example, photodiode 40 may generate charge associated with the first set of phases in the first pulse between assertions D1 and D2. As another example, photodiode 40 may generate charge associated with the second set of phases in the first pulse between assertions D2 and D3. As yet another example, photodiode 40 may generate charge associated with the first set of phases in the second pulse between assertions D3 and D4. This may continue until photodiode 40 generates the second set of phases in the last pulse between assertions D(N−1) and DN (e.g., at the end of the light source exposure time period). In other words, for each light pulse, the control circuitry may assert control signal AB1 twice, once for a first set of phases and once for a second set of phases.

Pixel 22 may include two separate charge storage structures such as storage diodes 50 and 60. As an example, storage diode 50 may store and integrate charges for the first set of phases of each of the pulses. As another example, storage diode 60 may store and integrate charges for the second set of phases for each of the pulses. As shown in FIG. 7, the control circuitry may alternatingly assert control signals TX3 (e.g., assertions F1, F2, F3, . . . , FN) and TX5 (e.g., assertions G1, G2, G3, . . . , GN) to transfer each charge generated by photodiode 40 to the corresponding storage diode (e.g., one of storage diodes 50 and 60 depending the corresponding set of phases associated with the generated charge).

While FIG. 7 shows a short pulse for asserting control signal AB1 for each of assertions D, this is merely illustrative. If desired, assertions D for control signal AB1 may extended. In this case, assertions F may occur for every two pulses of light source 70 and assertions G may also occur for every two pulse of light source 70 to account for the extended assertion of control signal AB1.

After a suitable number of pulses, storage diodes 50 and 60 may store respective charges integrated during the light source exposure time period. Depending on the row control scheme and the row in which a given pixel 22 is in, a row order waiting time period may separate the light source exposure time period from the readout time periods.

After a suitable amount of time for the row order waiting time period, readout time periods may begin for each of the charges stored at storage diodes 50 and 60. During the readout time periods, the control circuitry may continuously assert control signal RS (e.g., assertion H) to activate transistor 68 to perform readout operations for the row of pixels in which the given pixel 22 is located.

The control circuitry may assert control signal RST2 (e.g., assertion I) to activate transistor 66, thereby resetting floating diffusion region 56 to voltage VRD. The control signal may subsequently assert control signal SHR (e.g., assertion J) to perform a readout operation for a reset voltage level signal. Thereafter, the control circuitry may assert control signal TX4 (e.g., assertion K) to activate transistor 54, thereby electrically connecting storage diode 50 to floating diffusion region 56. The control circuitry may then assert control signal SHD (e.g., assertion L) to perform a readout operation for an image level signal associated with integrated charge stored at storage diode 50. This may be a correlated double sampling readout for the integrated charge stored at storage diode 50 and may conclude the readout operations for storage diode 50.

During the readout time period for storage diode 60, the control circuitry may assert control signal RST2 (e.g., assertion M) to activate transistor 66, thereby resetting floating diffusion region 56 to voltage VRD. The control signal may subsequently assert control signal SHR (e.g., assertion N) to perform a readout operation for a reset voltage level signal. Thereafter, the control circuitry may assert control signal TX6 (e.g., assertion O) to activate transistor 64, thereby electrically connecting storage diode 60 to floating diffusion region 56. The control circuitry may then assert control signal SHD (e.g., assertion P) to perform a readout operation for an image level signal associated with integrated charge stored at storage diode 60. This may be a correlated double sampling readout for the charge stored at storage diode 60.

Various embodiments have been described illustrative systems and methods for generating image data in ambient light conditions.

In particular, in some examples, an image sensor pixel may include a photosensitive element, a floating diffusion region, a charge storage structure interposed between the photosensitive element and the floating diffusion region, and a potential barrier structure (e.g., a transistor) that is interposed between the photosensitive element and the charge storage structure and that provides a potential barrier level based on an input signal at a control terminal (e.g., a gate terminal) of the potential barrier structure. The photosensitive element may be coupled to the control terminal of the potential barrier structure through a transistor. An additional transistor may couple a voltage source to the control terminal of the potential barrier structure. The charge storage structure may be interposed between the photosensitive element and the floating diffusion region along a first path, and an additional charge storage structure may be interposed between the photosensitive element and the floating diffusion region along a second path. A filter structure may be disposed over the photosensitive element and may pass infrared light to the photosensitive element.

If desired, a transistor may be interposed between the potential barrier structure and the charge storage structure, a transistor may be interposed between the potential barrier structure and the additional charge storage structure, a transistor may be interposed between the charge storage structure and the floating diffusion region, a transistor interposed between the additional charge storage structure and the floating diffusion region, an anti-blooming transistor may couple the photosensitive element to an additional voltage source, a reset transistor may couple the floating diffusion region to the additional voltage source, a source follower transistor may be coupled to the floating diffusion region, and a row select transistor may couple the source follower transistor to a pixel output path.

In some examples, an imaging system may include an IR light source configured to emit IR light and an image sensor having an array of image sensor pixels of the type described herein. More specifically an image sensor pixel may include a photosensitive element configured to receive a reflected version of the emitted IR light, a charge storage region coupled to the photosensitive element, and a transistor interposed between the photosensitive element and the charge storage region. The transistor has a gate terminal coupled to the photosensitive element. The photosensitive element may be configured to generate charge in response to ambient light and the gate terminal of the transistor is configured to receive a voltage associated with the charge generated in response to the ambient light. The transistor may be configured to provide a voltage barrier between the photosensitive element and the charge storage region based on the voltage associated with the charge generated in response to the ambient light. The photosensitive element may be configured to generate additional charge in response to the reflected version of the emitted light, and the voltage barrier is configured to pass only a portion of the additional generated charge to the charge storage region.

In some examples, an imaging system may include an image sensor pixel having a photosensitive element, a charge storage region, and a potential barrier structure interposed between the photosensitive element and the charge storage region. The photosensitive element may be configured to generate charge in response to ambient light and to set a voltage barrier level of the potential barrier structure based on the charge generated in response to the ambient light. The imaging system may further include control circuitry coupled to the image sensor pixel and to a light source, and configured to control the image sensor pixel to generate additional charge at the photosensitive element in response to light emitted from the light source. The photosensitive element may be configured to pass a portion of the additional charge to the charge storage region through the potential barrier structure.

If desired, the light emitted from the light source comprises a plurality of light pulse each having a corresponding first set of phases and a corresponding second set of phases. The additional charge may be generated based on the first set of phases in a given light pulse. The control circuitry may be configured to control the image sensor pixel to generate second additional charge at the photosensitive element based on the second set of phases in the given light pulse. The photosensitive element may be configured to pass a portion of the second additional charge to an additional charge storage region in the image sensor pixel through the potential barrier structure. The control circuitry may be configured to control the charge storage structure to integrate a first set of charges generated by the photosensitive element, each associated with the corresponding first set of phases in the light pulses and to control the additional charge storage structure to integrate a second set of charges generated by the photosensitive element, each associated with the corresponding second set of phases in the light pulses. The imaging system may further include readout circuitry coupled to the image sensor pixel and configured to perform a correlated double sampling readout on an integrated charge stored at the charge storage structure and to perform an additional correlated double sampling readout on an integrated charge stored at the additional charge storage structure.

The foregoing is merely illustrative of the principles of this invention and various modifications can be made by those skilled in the art without departing from the scope and spirit of the invention. The foregoing embodiments may be implemented individually or in any combination.

What is claimed is:

1. An image sensor pixel comprising:
a photosensitive element;
a floating diffusion region;
a charge storage structure interposed between the photosensitive element and the floating diffusion region; and
a potential barrier structure that is interposed between the photosensitive element and the charge storage structure and that provides a potential barrier level based on an input signal at a control terminal of the potential barrier structure, wherein the photosensitive element is coupled to the control terminal of the potential barrier structure.

2. The image sensor pixel defined in claim 1, further comprising:
a transistor that couples the photosensitive element to the control terminal of the potential barrier structure.

3. The image sensor pixel defined in claim 2, wherein the potential barrier structure comprises an additional transistor.

4. The image sensor pixel defined in claim 3, wherein the control terminal comprises a gate terminal of the additional transistor, and wherein the additional transistor has a first source-drain terminal coupled to the photosensitive element and a second source-drain terminal coupled to the charge storage structure.

5. The image sensor pixel defined in claim 2, further comprising:
an additional transistor that couples a voltage source to the control terminal of the potential barrier structure.

6. The image sensor pixel defined in claim 1, wherein the charge storage structure is interposed between the photosensitive element and the floating diffusion region along a first path, the image sensor pixel further comprising:
an additional charge storage structure interposed between the photosensitive element and the floating diffusion region along a second path.

7. The image sensor pixel defined in claim 6, further comprising:
a first transistor interposed between the potential barrier structure and the charge storage structure; and
a second transistor interposed between the potential barrier structure and the additional charge storage structure.

8. The image sensor pixel defined in claim 7, further comprising:
a third transistor interposed between the charge storage structure and the floating diffusion region; and
a fourth transistor interposed between the additional charge storage structure and the floating diffusion region.

9. The image sensor pixel defined in claim 8, further comprising:
an anti-blooming transistor that couples the photosensitive element to a voltage source;
a reset transistor that couples the floating diffusion region to the voltage source;
a source follower transistor coupled to the floating diffusion region; and
a row select transistor that couples the source follower transistor to a pixel output path.

10. The image sensor pixel defined in claim 1, further comprising:
a filter structure disposed over the photosensitive element and that passes infrared light to the photosensitive element.

11. An imaging system comprising:
a light source configured to emit light; and
an image sensor having an array of image sensor pixels, wherein a given image sensor pixel in the array of image sensor pixels comprises:
a photosensitive element configured to receive a reflected version of the emitted light;
a charge storage region coupled to the photosensitive element; and
a transistor interposed between the photosensitive element and the charge storage region, wherein the transistor has a gate terminal coupled to the photosensitive element.

12. The imaging system defined in claim 11, wherein the light source comprises an infrared light source configured to emit infrared light and the photosensitive element is configured to receive a reflected version of the emitted infrared light.

13. The imaging system defined in claim 12, wherein the photosensitive element is configured to generate charge in response to ambient light and the gate terminal of the transistor is configured to receive a voltage associated with the charge generated in response to the ambient light.

14. The imaging system defined in claim 13, wherein the transistor is configured to provide a voltage barrier between the photosensitive element and the charge storage region based on the voltage associated with the charge generated in response to the ambient light.

15. The imaging system defined in claim 14, wherein the photosensitive element is configured to generate additional charge in response to the reflected version of the emitted light and the voltage barrier is configured to pass only a portion of the additional generated charge to the charge storage region.

16. An imaging system comprising:
an image sensor pixel having a photosensitive element, a charge storage region, and a potential barrier structure interposed between the photosensitive element and the charge storage region, wherein the photosensitive element is configured to generate charge in response to ambient light and to set a voltage barrier level of the potential barrier structure based on the charge generated in response to the ambient light; and
control circuitry coupled to the image sensor pixel and to a light source, and configured to control the image sensor pixel to generate additional charge at the photosensitive element in response to light emitted from the light source, wherein the photosensitive element is configured to pass a portion of the additional charge to the charge storage region through the potential barrier structure.

17. The imaging system defined in claim 16, wherein the light emitted from the light source comprises a light pulse having a first set of phases and a second set of phases, wherein the additional charge is generated based on the first set of phases in the light pulse.

18. The imaging system defined in claim 17, wherein the control circuitry is configured to control the image sensor pixel to generate second additional charge at the photosensitive element based on the second set of phases, and the photosensitive element is configured to pass a portion of the second additional charge to an additional charge storage region in the image sensor pixel through the potential barrier structure.

19. The imaging system defined in claim 18, wherein the light emitted from the light source comprises additional light pulses, each having a corresponding first set of phases and a corresponding second set of phases, and wherein the control circuitry is configured to control the charge storage structure to integrate a first set of charges generated by the photosensitive element, each associated with the corresponding first set of phases in the additional light pulses and to control the additional charge storage structure to integrate a second set of charges generated by the photosensitive element, each associated with the corresponding second set of phases in the additional light pulses.

20. The imaging system defined in claim 19, further comprising:
readout circuitry coupled to the image sensor pixel and configured to perform a correlated double sampling readout on an integrated charge stored at the charge storage structure and to perform an additional correlated double sampling readout on an integrated charge stored at the additional charge storage structure.
